(19) United States
(12) Patent Application Publication
(10) Pub. No.: US 2026/0006929 A1
(43) Pub. Date: Jan. 1, 2026

(54) ISO IMAGE SENSORS AND METHOD OF FORMING THE SAME

(71) Applicant: Taiwan Semiconductor Manufacturing Company, Ltd., Hsinchu (TW)

(72) Inventors: Wen-Chang Kuo, Tainan City (TW); Yen-Yu Chen, Kaohsiung City (TW); Jen-Cheng Liu, Hsin-Chu City (TW); Yen-Ting Chiang, Tainan City (TW); Cheng-Yu Huang, Hsinchu (TW)

(21) Appl. No.: 18/760,075

(22) Filed: Jul. 1, 2024

(51) Int. Cl. H01L 27/146

(52) U.S. Cl. CPC H10F 39/806; H10F 39/024; H10F 39/8067; H10F 39/807

(57) ABSTRACT

Various embodiments of the present disclosure are directed towards a semiconductor device with a substrate where the substrate has a plurality of protrusions over a photodetector. An isolation structure is disposed in the substrate and laterally surrounds the photodetector. The isolation structure has a reflective element with a conductive material. A first dielectric layer is over the photodetector, where the first dielectric layer extends into the substrate and is disposed between the reflective element and the substrate. A top surface of the first dielectric layer is irregular. A second dielectric layer is on the first dielectric layer and over the photodetector. A top surface of the second dielectric layer over the plurality of protrusions is irregular. The second dielectric layer extends vertically into the substrate along a surface of the first dielectric layer. The second dielectric layer is disposed along sidewalls and a bottom surface of the reflective element.

### BACKGROUND

Image sensors are solid-state devices that are configured to convert incoming light (e.g., photons) into an electrical signal. The electrical signal is then provided to a processor that can convert the electrical signal to data that can be stored and/or viewed by a user. Integrated chips (ICs) with image sensors are used in a wide range of modern day electronic devices, such as cell phones, security cameras, medical devices, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-2 illustrate cross-sectional views of some embodiments of an image sensor including a high absorption structure and a trench isolation structure with a reflective element to improve quantum efficiency (QE) and modulation transfer function (MTF).

FIG. 3 illustrates a cross-sectional view of some embodiments of an image sensor including a high absorption structure and a trench isolation structure with a reflective element that has a varying height.

FIG. 4 illustrates a cross-sectional view of some other embodiments of an image sensor including a high absorption structure and a trench isolation structure.

FIGS. 5A and 5B illustrate cross-sectional views of some embodiments of an image sensor including recessed reflective elements and various configurations for an absorption layer of the high absorption structure.

FIG. 6A illustrates a cross-sectional view of some embodiments of an image sensor including a high absorption structure and a trench isolation structure with a reflective element.

FIG. 6B illustrates an enlarged cross-sectional view of some embodiments of the trench isolation structure of FIG. 6A.

FIG. 7 illustrates a cross-sectional view of some embodiments of an image sensor including a trench isolation structure and different shaped radiation absorption regions.

FIGS. 8-21 illustrate cross-sectional views of some embodiments of a method of forming an image sensor including a high absorption structure and a trench isolation structure with a reflective element.

FIGS. 22-25 illustrate cross-sectional views of some embodiments of a method of forming an image sensor including a high absorption structure and a trench isolation structure with a reflective element.

FIGS. 26-31 illustrate cross-sectional views of some embodiments of a method of forming an image sensor including a high absorption structure and a trench isolation structure with a reflective element.

FIG. 32 illustrates a flow diagram of some embodiments of a method of forming an image sensor including a high absorption structure and a trench isolation structure with a reflective element to improve QE and MTF performance.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Image sensors (e.g., semiconductor image sensors (CISs)) may include a plurality of pixel sensors disposed on a substrate. The pixel sensors include photodetectors that are configured to convert energy from a radiation source (e.g., light, infrared radiation, x-rays, etc.) into electrical current. Over time, the semiconductor industry has reduced the size of pixel regions of the pixel sensors in the substrate, so as to increase a number of pixel regions in the image sensor integrated chip (IC). Increasing the number of pixel regions in a CIS IC increases the resolution of an image captured by the CIS IC. However, as the size of the pixel regions get smaller, the pixel regions become closer together and crosstalk between adjacent pixel regions increases.

Crosstalk occurs when incident light directed towards one pixel region is undesirably sensed by another pixel region, thereby degrading the quality of an image captured by a CIS integrated chip. To mitigate crosstalk, the photodetectors can be separated from one another by isolation structures that are configured to mitigate electrical or photonic crosstalk between photodetectors. In some aspects, the isolation structures are formed from one or more of a back-side or a front-side of the substrate containing the photodetectors. However, isolation structures can affect the quantum efficiency (QE) and modulation transfer function (MTF) of the image sensor. For example, an isolation structure that is formed from an oxide can have high QE and a low MTF. However, by forming the isolation structure from a metal, the MTF can be improved at the cost of lowering the QE.

Various aspects of the present disclosure are directed towards an image sensor IC with a trench isolation structure formed from the back-side of the substrate having a reflective element that is conductive to improve the MTF performance of the image sensor. The trench isolation structure is combined with a high absorption structure to improve the QE of the image sensor. The high absorption structure overlies the photodetectors of the image sensor in a radiation absorption region. The high absorption structure includes a plurality of dielectric layers to facilitate wavelength matched absorption. In the radiation absorption region, the substrate underlying the high absorption structure has a plurality of protrusions to improve photon absorption. The high absorption structure is disposed along and conforms to a shape of the plurality of protrusions, thereby increasing a light receiving surface area for light incident on the substrate and efficiently guiding incident light to the underlying photodetector. As such, the trench isolation structure and the high absorption structure enhance both MTF performance and QE thereby minimizing crosstalk and noise within the pixel region of the image sensor.

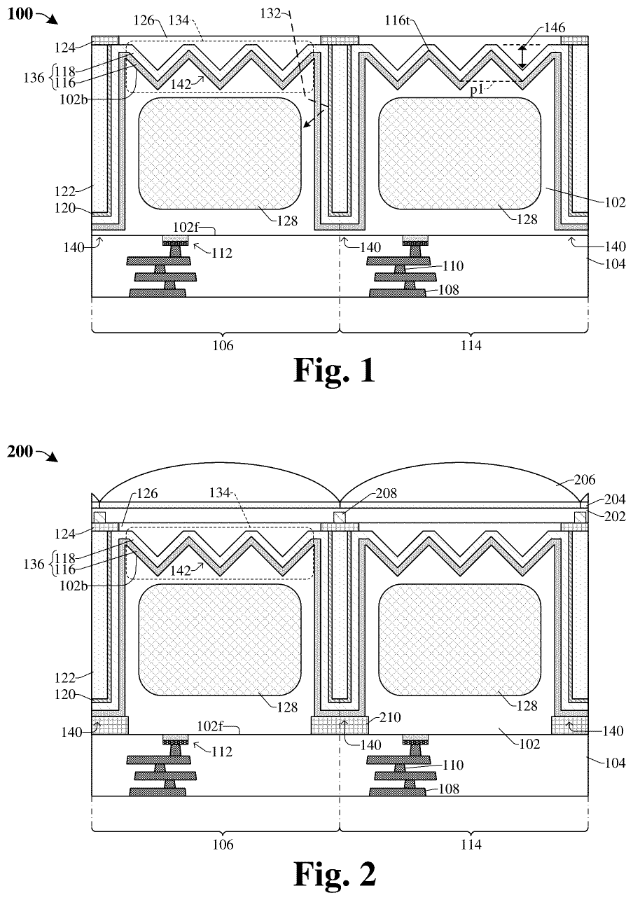

FIG. 1 illustrates a cross-sectional view of some embodiments of an image sensor 100 including an absorption structure 126 and a trench isolation structure 140 with a reflective element 122.

The image sensor 100 comprises a substrate 102 having a plurality of pixel regions 106, 114. In some embodiments, the substrate 102 comprises a semiconductor body (e.g., bulk silicon) and/or has a first doping type (e.g., p-type). The plurality of pixel regions 106, 114 respectively comprise a photodetector 128 configured to convert incident radiation (e.g., photons) into an electrical signal (i.e., to generate electron-hole pairs from the incident radiation). In some embodiments, the photodetector 128 is an image sensing element or a photodiode. In some embodiments, the photodetector 128 may comprise a second doping type (e.g., n-type) opposite the first doping type.

The substrate 102 has a front-side surface 102f and a back-side surface 102b. A dielectric structure 104 is arranged on the front-side surface 102f of the substrate 102. A plurality of pixel devices 112 are disposed along the front-side surface 102f of the substrate 102 and disposed within the dielectric structure 104. In some embodiments, the plurality of pixel devices 112 may be a plurality of transistor devices. In some embodiments, the plurality of pixel devices 112 may comprise a gate electrode, a gate dielectric layer, a source, and a drain. The pixel devices 112 are electrically coupled to one another and/or other semiconductor devices (not shown) by way of a plurality of conductive wires 108 and a plurality of vias 110.

In various embodiments, the electrical signal generated by the photodetector 128 of the plurality of pixel regions 106, 114 can be read by the plurality of pixel devices 112. For example, the plurality of pixel devices 112 may comprise one or more transfer transistors configured to selectively form a conductive channel in the substrate 102 between a floating diffusion node (not shown) and an adjacent photodetector 128 to transfer accumulated charge (e.g., from absorbed incident radiation) in the photodetector 128 to the floating diffusion node.

A trench isolation structure 140 (also referred to as an isolation structure) extends into the substrate 102 from the back-side surface 102b. The trench isolation structure 140 is disposed between the plurality of pixel regions 106, 114 and separates photodetectors 128 of the plurality of pixel regions 106, 114 from one another. In some embodiments, the trench isolation structure 140 laterally surrounds each of the photodetectors 128. In some embodiments, the trench isolation structure 140 is a deep trench isolation (DTI) structure. The back-side surface 102b of the substrate 102 over the photodetector 128 comprises a radiation absorption region 134 characterized by a non-planar surface defined by a plurality of protrusions 142 arranged in a periodically repeating pattern. The plurality of protrusions 142 are arranged over a top portion of the photodetectors 128. In some embodiments, the plurality of protrusions 142 are triangular or pyramidal structures. In some embodiments, the plurality of protrusions 142 have a protrusion height of 2000 Angstroms (A) to 5000 A, or from 2500 A to 4500 A or 3000 A to 4000 A. In other embodiments, the protrusion height is 3000 A, 3500 A or 4000 A. It is appreciated that the density of repeating pattern of the triangular structures can be different than illustrated in image sensor 100. For example, the image sensor 100 is shown with four triangular shaped protrusions, but in other embodiments (not shown), a number of triangular shaped protrusions can be greater or less than four. Additionally, the height and pitch (size) of the triangular shaped protrusions can be configured differently than shown. The number of triangular shaped protrusions and the size of the triangular shaped protrusions can be configured to maximize absorption of one or more wavelengths of electromagnetic radiation through the high absorption structure 136. The first and second dielectric layers 116, 118 are disposed along the repeating pattern of triangular shaped protrusions and form a repeating pattern of zig-zag layers over the photodetector 128.

In some embodiments, the trench isolation structure 140 includes a reflective element 122 and a liner layer 120 along sidewalls and a bottom surface of the reflective element 122. Further, a high absorption structure 136 extends over the photodetectors on the back-side surface 102b of the substrate 102 within the radiation absorption region 134. The high absorption structure 136 comprises a plurality of dielectric layers that includes a first dielectric layer 116 and a second dielectric layer 118 that extend along surfaces of the reflective element 122. In some embodiments, portions of the first and second dielectric layers 116, 118 arranged between the reflective element 122 and the substrate 102 are part of the trench isolation structure 140. An absorption layer 126 is disposed over the high absorption structure 136 in the radiation absorption region 134 and a dielectric cap 124 is disposed over the trench isolation structure 140 separating the absorption layer 126 of pixel region 106 from the absorption layer 126 of pixel region 114. As such, the dielectric cap 124 is disposed on the reflective element 122, and the absorption layer 126 extends between sidewalls of the dielectric cap 124. In some embodiments, the dielectric cap 124 and the absorption layer 126 have top horizontal surfaces that are coplanar or substantially coplanar with one another. In some embodiments, the dielectric cap 124 and the absorption layer 126 comprise a same material. In other embodiments, the dielectric cap 124 comprises a first material and the absorption layer 126 comprises a second material different from the first material. As the dielectric cap 124 is aligned over the reflective element 122, the dielectric cap 124 comprising the first material different from the second material can help increase isolation between pixel regions while maximizing radiation transmission through the absorption layer 126.

The reflective element 122 is configured to reflect electromagnetic radiation incident on the back-side surface 102b to a corresponding photodetector 128. In some embodiments, the reflective element 122 can be or comprise metal, copper, aluminum, tungsten, or another suitable conductive material. Because the reflective element 122 is configured to reflect electromagnetic radiation, the reflective element 122 reduces crosstalk between adjacent pixel regions (e.g., pixel region 106 and pixel region 114). For example, when incident radiation 132 directed towards pixel region 106 strikes an interface between one or more of the absorption layer 126, the high absorption structure 136, and the substrate 102, a portion of the incident radiation 132 may be reflected towards the pixel region 114 which is adjacent to pixel region 106. The reflective element 122 is configured to coherently reflect the portion of the incident radiation 132 back toward the pixel region 106, thereby reducing crosstalk and further increasing the MTF performance of the image sensor 100.

The high absorption structure 136 overlies and conforms to a shape of the plurality of protrusions 142. In some embodiments, the first and second dielectric layers 116, 118 of the high absorption structure 136 separate the reflective element 122 from the substrate 102. The first dielectric layer extends vertically or substantially vertical through the back-side surface 102b into the substrate 102 and is disposed between the reflective element 122 and the substrate 102. The second dielectric layer 118 is disposed on the first dielectric layer 116, where the second dielectric layer 118 extends vertically into the substrate along a surface of the first dielectric layer 116. The second dielectric layer is disposed along sidewalls and a bottom surface of the reflective element 122. In some embodiments, the liner layer 120 is disposed between the reflective element 122 and the second dielectric layer 118, and the liner layer 120 is disposed along the bottom surface of the reflective element 122. In some embodiments, the liner layer 120 extends from a horizontal surface that is common with a top surface of the reflective element 122 and the second dielectric layer 118.

In some embodiments, the liner layer 120 is a diffusion barrier layer. The liner layer 120 can prevent diffusion between the reflective element 122 and the second dielectric layer 118 and reduce capacitance between the substrate 102 and the reflective element 122. In some embodiments, the liner layer 120 minimizes light absorption by the reflective element 122 thereby maximizing light reflection within the plurality of pixel regions 106, 114. In some embodiments, the liner layer 120 can be or comprise an alloy of or material stack including titanium, aluminum, titanium aluminum, tantalum, tantalum nitride, some other conductive material or metal. In other embodiments, the liner layer 120 can be or comprise a low-k dielectric material such as silicon dioxide, silicon carbonitride, boron oxide, a silica, or the like. As used herein, a low-k dielectric material is a dielectric material with a dielectric constant less than 3.9, or a dielectric constant less than 2.7.

In some embodiments, the first dielectric layer 116 and the second dielectric layer 118 comprise a same material, in other embodiments, the first dielectric layer 116 and the second dielectric layer 118 comprise different dielectric materials relative to one another. For example, the first and second dielectric layers 116, 118 can both be a low-k dielectric material or an oxide such as a silicon oxide (e.g., SiO₂, SiCO, etc.) or a boron oxide (e.g., borosilicate glass (BSG), B₂O₃). In other embodiments, the first dielectric layer 116 is a high-k dielectric material (e.g., aluminum oxide, hafnium oxide, etc.) and the second dielectric layer 118 is an oxide. As used herein, a high-k dielectric material is a dielectric material with a dielectric constant greater than 3.9. Furthermore, the absorption layer 126 can be or include an oxide (e.g., one or more SiO₂, SiCO, B₂O₃, etc.). In some embodiments, the absorption layer 126 comprises the same material as the second dielectric layer 118, in other embodiments, the absorption layer 126 is a different material (e.g., different oxide or different density of oxide) relative to the second dielectric layer 118.

The high absorption structure 136 extends along a top surface (e.g., the back-side surface 102b) of the substrate 102 in the radiation absorption region 134 over the photodetector 128. The first and second dielectric layers 116, 118 are disposed over the plurality of protrusions 142 on the back-side surface 102b of the substrate 102. As such, the first and second dielectric layers 116, 118 have a plurality of surfaces that conform to a shape of the plurality of protrusions 142 and increase a light receiving surface area for light incident on the back-side surface 102b of the substrate 102. In some examples, a top surface of the second dielectric layer 118 periodically extends from above a top surface 116t of the first dielectric layer 116 to a plane p1 below the top surface of the first dielectric layer 116. The absorption layer 126 is disposed on the second dielectric layer 118 and extends into a periodically repeating recess 146 below a top most surface of the second dielectric layer 118 aligned over the periodically repeating pattern of the plurality of protrusions 142.

The shape and/or material of the first and second dielectric layers 116, 118 in the high absorption structure 136 in conjunction with the absorption layer 126 and the plurality of protrusions 142 enhance light transmission for a desired wavelength of light towards the photodetectors 128. Thus, the first and second dielectric layers 116, 118 and the absorption layer 126 improve the QE of image sensor 100. As such, by combining the plurality of protrusions 142 with the high absorption structure 136 in the radiation absorption region 134, and the reflective element 122 within the trench isolation structure 140, the image sensor 100 can achieve improved MTF performance and improved QE.

FIG. 2 illustrates a cross-sectional view of some embodiments of an image sensor 200 including a high absorption structure 136 and a trench isolation structure 140 with a reflective element 122. The image sensor 200 of FIG. 2 illustrates other embodiments of the image sensor 100 of FIG. 1, where the image sensor 200 includes a plurality of micro-lenses 206, a plurality of light filters 204, and a grid structure 208 disposed over the back-side surface 102b of the substrate 102.

The image sensor 200 includes a lower dielectric layer 202 disposed on the back-side surface 102b of the substrate 102. A grid structure 208 is disposed within the lower dielectric layer 202 and aligned between the photodetector 128 of the plurality of pixel regions 106, 114. A plurality of light filters 204 are disposed on the lower dielectric layer 202. A plurality of micro-lenses 206 are disposed on the plurality of light filters 204.

The plurality of micro-lenses 206 are configured to direct incident light towards the photodetector 128. The plurality of light filters 204 each comprise a material configured to pass a first range of wavelengths while blocking a second range of wavelengths. The grid structure 208 and the trench isolation structure 140 provide electrical and/or optical isolation between the plurality of pixel regions 106, 114. The photodetector 128 is configured to absorb incident light (e.g., photons) received through the micro-lenses 206 and generate respective electrical signals corresponding to the incident light.

The image sensor 200 further includes a shallow trench isolation (STI) structure 210 disposed within the substrate 102 and aligned under the trench isolation structure 140. The STI structure 210 can comprise one or more dielectric materials and is arranged on the front-side surface 102f of the substrate. In some embodiments the STI structure 210 can extend from the front-side surface 102f to a bottom surface of the trench isolation structure 140. In other embodiments (not shown), the substrate 102 separates the STI structure 210 from the trench isolation structure 140. In some embodiments, a width of the STI structure 210 is wider than that of a width of the trench isolation structure 140. In other embodiments (not shown) a width of the STI structure 210 is narrower the width of the trench isolation structure 140. The STI structure can provide additional electrical isolation between photodetector 128 of the plurality of pixel regions 106, 114 and/or reduce leakage currents of the plurality of pixel devices 112.

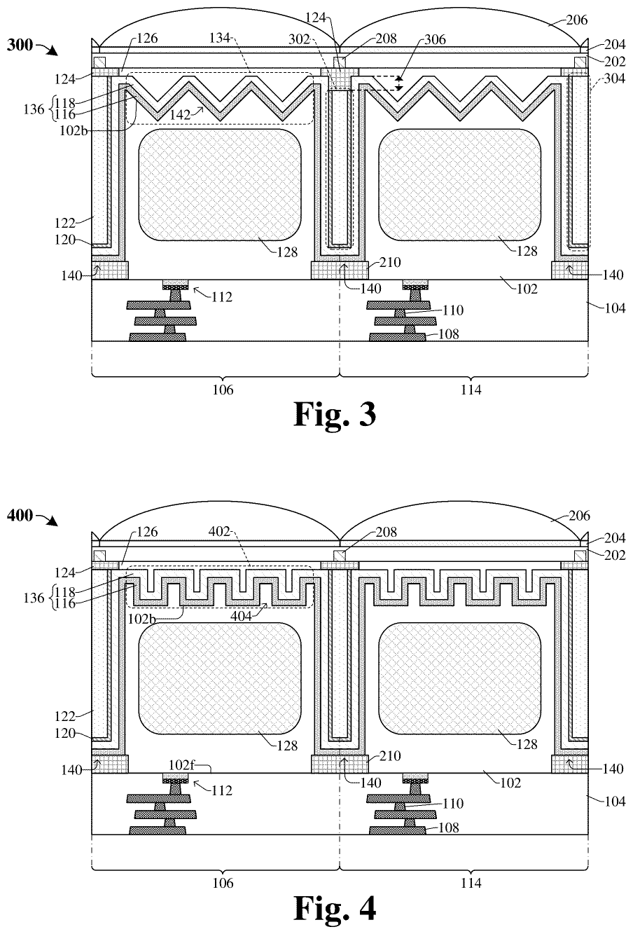

FIG. 3 illustrates a cross-sectional view of some embodiments of an image sensor 300 with different height reflective elements.

Image sensor 300 shows the reflective element 122 with differing heights. The reflective element 122 is shown with a first reflective portion 302 disposed between pixel region 106 and pixel region 114, and a second reflective portion 304 laterally offset from the pixel region 106. A height of the first reflective portion 302 is less than a height of the second reflective portion 304. For example, the first and second reflective portions 302, 304 have bottom surfaces that are substantially level with one another. The second reflective portion 304 has a top surface that is common with a top surface of the second dielectric layer 118. The first reflective portion 302 has a top surface that is recessed below the top surface of the second dielectric layer 118 by a vertical height offset 306. As such, a height difference between the first and second reflective portions 302, 304 is the vertical height offset 306. Therefore, the top surface of the first reflective portion 302 is recessed below the top surface of the second reflective portion 304.

The dielectric cap 124 aligned over the first reflection portion 302 extends between inner sidewalls of the second dielectric layer 118 and extends from the first reflection portion 302 to the lower dielectric layer 202. In some embodiments, a top surface of the liner layer 120 that lines the first reflective portion 302 is substantially level with the top surface of the first reflective portion 302. As such, in some embodiments, the dielectric cap directly contacts top surfaces of the liner layer 120 and the first reflective portion 302 below the top surface of one or more of the first or second dielectric layers 116, 118. In some embodiments, a top portion of the dielectric cap 124 that extends above the second dielectric layer 118 has a width that is greater than a width of a bottom portion of the dielectric cap 124 that extends between sidewalls of the second dielectric layer 118 located below the top surface of the second dielectric layer 118.

The height of reflective element 122 can be configured to reflect one or more wavelengths of electromagnetic radiation toward the photodetector 128. For example, in some embodiments, the height of one or more portions of the reflective element 122 surrounding photodetector 128 of pixel region 106 can vary or be a fixed height that is different relative to photodetector 128 of pixel region 114. Furthermore, it is appreciated that the width or thickness of the reflective element 122 can be varied where, for example (not pictured), a width or a vertical profile (e.g., tapering) of the first reflective portion 302 is different than a width or a vertical profile of the second reflective portion 304. The reflective element 122 height or vertical profile can be configured based on the one or more wavelengths of electromagnetic radiation so as to achieve coherent reflections off of the reflective element 122 and towards the photodetector 128. That is, the reflected energy constructively interferes so as to maximize light received by the photodetector for the one or more wavelengths.

FIG. 4 illustrates a cross-sectional view of some embodiments of an image sensor 400 with a plurality of protrusions 404 that are rectangular in shape.

Image sensor 400 provides an alternative profile for a radiation absorption region 402 relative to the radiation absorption region 134 of FIGS. 1-3. The back-side surface 102b of the substrate 102 is non-planar and defined by a plurality of protrusions 404 arranged in a periodically repeating pattern of rectangular shaped protrusions (also referred to as trench shapes). The first and second dielectric layers 116, 118 are disposed along the repeating pattern of rectangular shaped protrusions, such that the first and second dielectric layers 116, 118 form a repeating pattern of meandered layers over the photodetector 128 thereby forming the high absorption structure 136 over the photodetector 128. It is appreciated that the density of repeating pattern of rectangular shaped protrusions can be different than illustrated in image sensor 400. For example, image sensor 400 is shown with five rectangular shaped protrusions, but in other embodiments (not shown), a number of rectangular shaped protrusions can be greater or less than five. Additionally, the height and width (size) of the rectangular shaped protrusions can be configured differently than shown. The number of rectangular shaped protrusions and the size of the rectangular shaped protrusions can be configured to maximize absorption of one or more wavelengths of electromagnetic radiation through the high absorption structure 136. It is appreciated that while FIGS. 1-3 are shown with the plurality of protrusions 142 that are triangular structures, FIGS. 1-3 can be modified to replace the triangular structures with the rectangular structures of image sensor 400, and vice-versa.

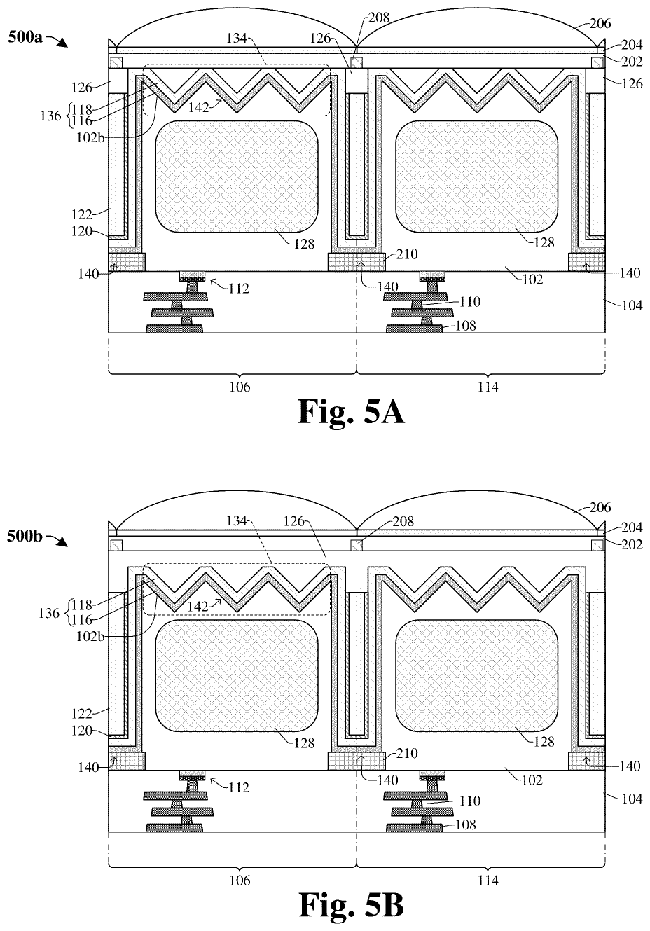

FIG. 5A illustrates a cross-sectional view of some embodiments of an image sensor 500a including a high absorption structure 136 and a trench isolation structure 140 having a reflective element 122.

Image sensor 500a shows alternative embodiments where rather than a dielectric cap 124 (e.g., see FIG. 1) disposed on the reflective element 122, the absorption layer 126 is disposed on the reflective element 122. The absorption layer 126 is disposed along the second dielectric layer 118, where the absorption layer 126 extends from a lower surface of the second dielectric layer 118 to a top surface of the second dielectric layer 118 in the radiation absorption region 134. The reflective element 122 and the liner layer 120 are recessed below top surfaces of one or more of the first and second dielectric layers 116, 118. In some embodiments, the absorption layer 126 is part of the trench isolation structure 140 and disposed on a top surface of the reflective element 122 and a top surface of the liner layer 120. As such, the absorption layer 126 extends from the reflective element 122 and the liner layer 120 to the top surface of the second dielectric layer 118. Accordingly, the absorption layer 126 is disposed between inner sidewalls of the second dielectric layer 118 and extends from a horizontal surface common with top surfaces of the liner layer 120 and the reflective element 122 to a top surface of the second dielectric layer 118. The image sensor 500a can achieve improved MTF performance and improved QE with simpler fabrication processes.

FIG. 5B illustrates a cross-sectional view of some embodiments of an image sensor 500b with a high absorption structure 136 and a trench isolation structure 140 having a reflective element 122.

Image sensor 500b shows alternative embodiments of the absorption layer 126 relative to image sensor 500a. As shown in image sensor 500b, the absorption layer 126 extends from the reflective element 122, the liner layer 120, and the lower surface of the second dielectric layer 118 to a plane arranged above the second dielectric layer 118. In some embodiments, a height of the absorption layer 126 can be configured to extend above the second dielectric layer 118. The height of the absorption layer 126 can be configured to maximize absorption from one or more wavelengths of electromagnetic radiation. While image sensors 500a and 500b are shown with a plurality of protrusions 142 that are triangular structures, it is understood that the plurality of protrusions 142 of image sensors 500a and 500b can be rectangular structures, for example, as shown in FIG. 4 (and vice-versa).

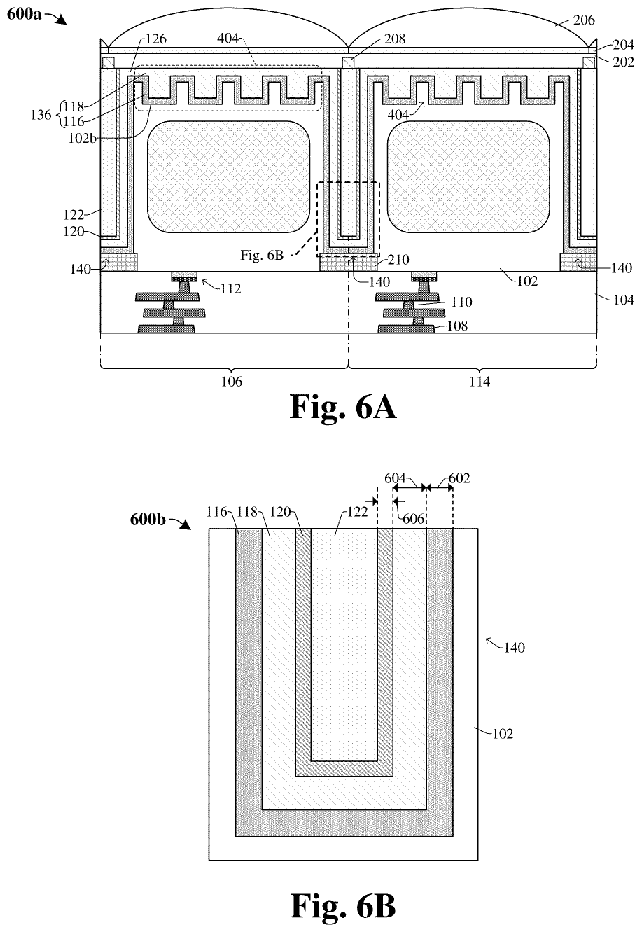

FIG. 6A illustrates a cross-sectional view of some embodiments of an image sensor 600a with a high absorption structure 136 and a trench isolation structure 140 having a reflective element 122.

Image sensor 600a shows alternative embodiments relative to image sensor 400 of FIG. 4, where the dielectric cap 124 and the absorption layer 126 of FIG. 4 are omitted from image sensor 600a. As such, the lower dielectric layer 202 is disposed on the second dielectric layer 118, the liner layer 120, and the reflective element 122. Furthermore, the grid structure 208 is disposed on the reflective element. Thus, the second dielectric layer 118 has a flat top surface and a bottom surface that is irregular and extends below a top surface of the first dielectric layer 116. The image sensor 600a can achieve improved MTF performance and improved QE with simpler fabrication processes.

FIG. 6B illustrates a cross-sectional view of some embodiments of an image sensor 600b with a trench isolation structure 140.

Image sensor 600b shows a lower portion of the trench isolation structure 140 of FIG. 6A. In particular, image sensor 600b shows relative thicknesses or widths of the liner layer 120, the first dielectric layer 116 and the second dielectric layer 118. In some embodiments, the first dielectric layer 116 has a first thickness 602 of 50 angstroms (A) to 1000 A. In some embodiments, the second dielectric layer 118 has a second thickness 604 of 20 A to 100 A. In some embodiments, the liner layer 120 has a third thickness of 0 A to 500 A. As such, the thicknesses 602, 604, 606 can be configured to achieve improved MTF performance and improved QE for image sensor 600b.

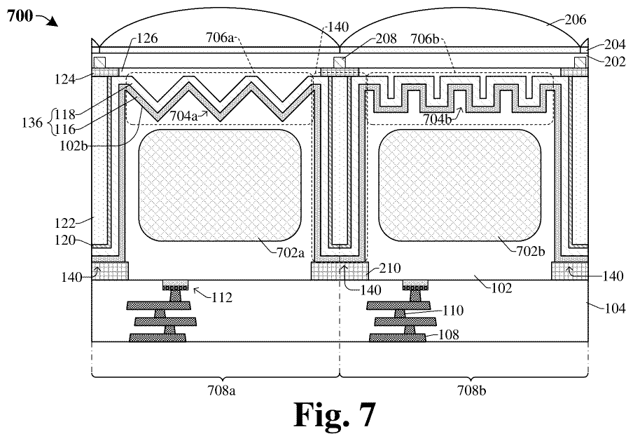

FIG. 7 illustrates a cross-sectional view of some embodiments of an image sensor 700 including a trench isolation structure 140 and different radiation absorption regions.

Image sensor 700 shows pixel region 708a with a radiation absorption region 706a having a first plurality of protrusions 704a that are triangular structures on the back-side surface 102b of the substrate 102. Aspects related to triangular structures discussed previously in accordance with FIGS. 1-3, 5A, and 5B apply also to FIG. 7. Laterally offset from pixel region 708a is pixel region 708b with a radiation absorption region 706b having a second plurality of protrusions 704b that are rectangular structures on the back-side surface 102b of the substrate 102. Aspects related to rectangular structures discussed previously in accordance with FIGS. 4 and 6A apply also to FIG. 7. As such, the radiation absorption regions 706a, 706b have different structures for each respective first and second plurality of protrusions 704a, 704b.

In some embodiments, the pixel region 704a has a first photodetector 702a disposed within the substrate 102 and the pixel region 704b has a second photodetector 702b disposed within the substrate 102. The trench isolation structure 140 is spaced between the first photodetector 702a and the second photodetector 702b. The first plurality of protrusions 704a overlies the first photodetector 702a and the second plurality of protrusions 704b overlies the second photodetector 702b. The first plurality of protrusions 704a have a first shape and the second plurality of protrusions have a second shape different from the first shape.

Accordingly, the different shaped first and second plurality of protrusions 704a, 704b can provide tailored light absorption for different wavelengths of electromagnetic radiation. For example, the first plurality of protrusions 704a can be configured to efficiently absorb a first wavelength and the second plurality of protrusions 704b can be configured to efficiently absorb a second wavelength where the first wavelength is different than the second wavelength. Accordingly, each pixel region can be configured for a specified wavelength according to a structure of the pixel region's radiation absorption region and trench isolation structure 140 to achieve improved MTF performance and improved QE for the image sensor 700.

It is appreciated that in some embodiments, the first plurality of protrusions 704a can have four triangular structures and the second plurality of protrusions 704b can have five rectangular structures. As such, the first plurality of protrusions 704a can have less protrusions relative to the second plurality of protrusions 704b. In other embodiments (not shown) the first plurality of protrusions 704a can have more protrusions relative to the second plurality of protrusions 704b. The number of protrusions and the size of the protrusions for one or more of the first or second plurality of protrusions 704a, 704b can be configured according to one or more wavelengths for absorption as discussed previously in accordance with FIGS. 1 and 4.

While FIGS. 1-7 may be shown individually with a particular arrangement of the radiation absorption region or the isolation structure, it is understood that particular features from one figure can be substituted with features from another figure.

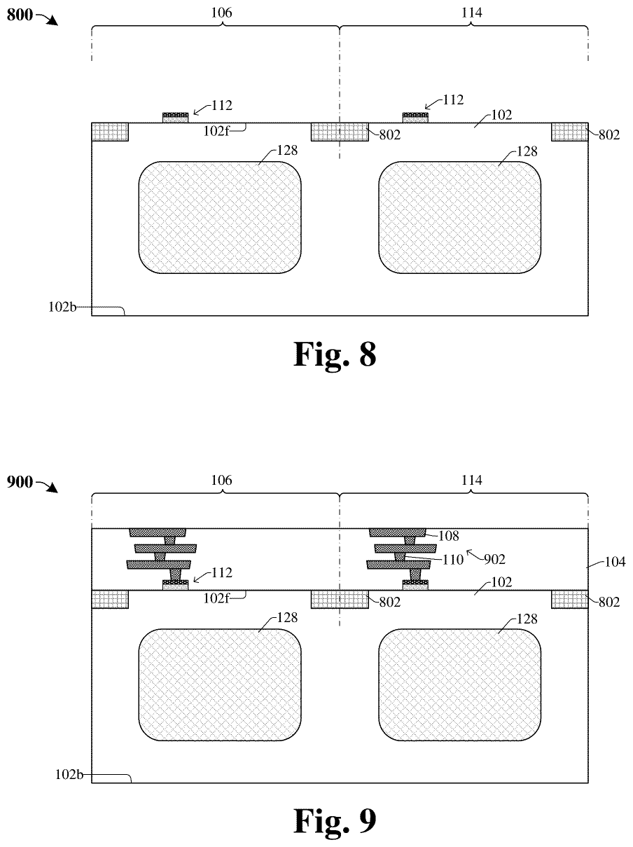

FIGS. 8-21 illustrate various views 800-2100 of some embodiments of a method for forming a semiconductor device or an image sensor including a high absorption structure and a trench isolation structure with a reflective element. Although the various views 800-2100 shown in FIGS. 8-21 are described with reference to the method, it will be appreciated that the structures shown in FIGS. 8-21 are not limited to the method but rather may stand alone separate of the method. Further, although FIGS. 8-21 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part. Furthermore, although the method describes the formation of a back-side image (BSI) sensor, it will be appreciated that the disclosed trench isolation structure may also be used with front-side image (FSI) sensor.

As shown in cross-sectional view 800, a substrate 102 is provided with a back-side surface 102b and a front-side surface 102f. The substrate 102 may be any type of semiconductor body (e.g., silicon, SiGe, SOI, etc.), as well as any other type of semiconductor and/or epitaxial layers associated therewith. For example, in some embodiments, the substrate 102 may comprise a base substrate and an epitaxial layer. In some embodiments, the substrate 102 may comprise a silicon substrate.

A photodetector 128 is formed within the plurality of pixel regions 106, 114 of the substrate 102. In some embodiments, the photodetector 128 may comprise photodiodes formed by implanting one or more dopant species into the front-side surface 102f of the substrate 102. For example, the photodiodes may be formed (not shown) by selectively performing a first implantation process (e.g., according to a masking layer) to form a first region having a first doping type (e.g., n-type), and subsequently performing a second implantation process to form a second region abutting the first region and having a second doping type (e.g., p-type) different than the first doping type. In some embodiments a floating diffusion well (not shown) may also be formed using one of the first or second implantation processes.

A plurality of pixel devices 112 are formed along the front-side surface 102f of the substrate 102 within the plurality of pixel regions 106, 114. In various embodiments, the plurality of pixel devices 112 may correspond to a transfer transistor, a source-follower transistor, a row select transistor, and/or a reset transistor. In some embodiments, the plurality of pixel devices 112 may be formed by depositing a gate dielectric film and a gate electrode film on the front-side surface 102f. The gate dielectric film and the gate electrode film are subsequently patterned to form a gate dielectric layer and a gate electrode. Sidewall spacers may be formed on the outer sidewalls of the gate electrode. In some embodiments, the sidewall spacers may be formed by depositing a spacer layer (e.g., a nitride, an oxide, etc.) onto the front-side surface 102f of the substrate 102 and selectively etching the spacer layer to form the sidewall spacers.

In some embodiments, one or more shallow trench isolation (STI) structures 802 may be formed within the front-side surface 102f of the substrate 102 on opposing sides of the plurality of pixel regions 106, 114. Therefore, the STI structures 802 are disposed between the photodetector 128 of the plurality of pixel regions 106, 114. The STI structures 802 may be formed (not shown) by selectively etching the front-side surface 102f of the substrate 102 to form shallow trenches and subsequently forming one or more dielectric materials within the shallow trenches. In some embodiments, the STI structures 802 may be formed prior to formation of the plurality of pixel devices 112 and/or the photodetector 128.

As shown in cross-sectional view 900 of FIG. 9, a dielectric structure 104 is formed on the front-side surface 102f of the substrate 102. A plurality of conductive interconnect layers 902 are formed within the dielectric structure 104 and formed along the front-side surface 102f of the substrate 102. In some embodiments the dielectric structure 104 comprises a plurality of stacked inter-level dielectric (ILD) layers, while the plurality of conductive interconnect layers 902 comprise alternating layers of conductive wires 108 and a plurality of vias 110. In some embodiments, one or more of the plurality of conductive interconnect layers 902 may be formed (not shown) using a damascene process (e.g., a single damascene process or a dual damascene process). The damascene process is performed by forming an ILD layer over the front-side surface 102f of the substrate 102, etching the ILD layer to form a via hole and/or a metal trench, and filling the via hole and/or metal trench with a conductive material. In some embodiments, the ILD layer may be deposited by a physical vapor deposition technique (e.g., chemical vapor deposition (CVD), plasma vapor deposition (PVD), plasma enhanced CVD (PE-CVD), atomic layer deposition (ALD), etc.) and the conductive material may be formed using a deposition process and/or a plating process (e.g., electroplating, electro-less plating, etc.). In various embodiments, the plurality of conductive interconnect layers 902 may comprise tungsten, copper, or aluminum copper, for example.

As shown in cross-sectional view 1000 of FIG. 10, the part as fabricated through FIG. 9 is first flipped about the horizontal axis. A first patterned masking layer 1002 is formed along the back-side surface 102b of the substrate 102. The first patterned masking layer 1002 comprises sidewalls defining openings 1004 along the back-side surface 102b of the substrate 102. In some embodiments, the first patterned masking layer 1002 may be formed by depositing a layer of photosensitive material (e.g., a positive or negative photoresist) along the back-side surface 102b of the substrate 102. The layer of photosensitive material is selectively exposed to electromagnetic radiation according to a photomask. The electromagnetic radiation modifies a solubility of exposed regions within the photosensitive material to define soluble regions. The photosensitive material is subsequently developed to define the openings 1004 within the photosensitive material by removing the soluble regions. The openings 1004 are formed directly overlying the photodetector 128 within the plurality of pixel regions 106, 114.

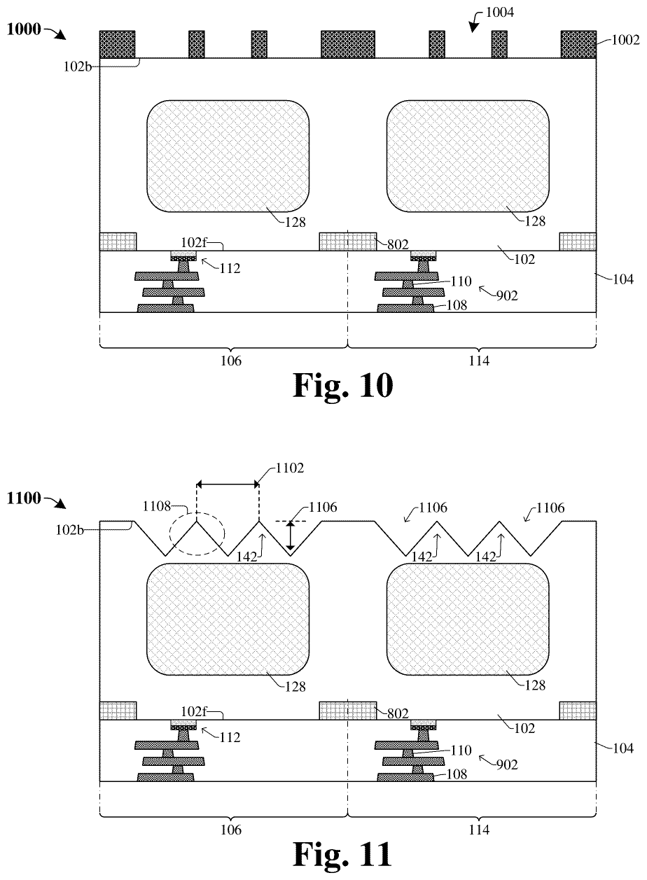

As shown in cross-sectional view 1100 of FIG. 11, a first etching process is performed on the back-side surface 102b of the substrate 102 according to the first patterned masking layer 1002 of FIG. 10. The first etching process is performed by exposing the substrate 102 to one or more etchants with the first patterned masking layer 1002 in place. The one or more etchants remove portions of the substrate 102 to define a plurality of recesses 1106 arranged between a plurality of protrusions 142 extending outward from the substrate 102. The plurality of protrusions 142 form a repeating periodic pattern of shapes of individual protrusions 1108, and have an outer border confined within the projected area of the pixel region 106. In some embodiments, the first etching process may comprise a dry etching process. For example, the first etching process may comprise a coupled plasma etching process, such as an inductively coupled plasma (ICP) etching process or a capacitive coupled plasma (CCP) etching process. In other embodiments, the first etching process may comprise a wet etching process.

In some embodiments, the repeating shape of the individual protrusions 1108 has a triangular or pyramidal shape with a shape width (or pitch) and a shape height that is commiserate with a height of one of the plurality of recesses 1106. The individual protrusions 1108 are separated from one another by a shape distance 1102. The shape height and width (or pitch) can be configured to maximize transmission of a particular wavelength of light to the photodetector 128. In some embodiments (not shown), the plurality of protrusions 142 are rectangular in shape, for example, as seen in FIG. 4.

As shown in cross-sectional view 1200 of FIG. 12, a second etching process is performed on the back-side surface 102b of the substrate 102 according to a second patterned masking layer 1202. The second etching process forms an isolation trench 1204 and which will subsequently accommodate the trench isolation structure 140. The isolation trench 1204 expose inner sidewalls of the substrate 102 and a top surface of the STI structures 802. The isolation trench 1204 is formed laterally surrounding the photodetector 128 of plurality of pixel regions 106, 114. The second etching process is performed by exposing unmasked regions of the substrate 102 to one or more etchants, which remove portions of the substrate 102 in the unmasked regions to form the isolation trench 1204 for the trench isolation structure 140. In some embodiments, the isolation trench 1204 has tapered sidewalls that cause a width of the isolation trench 1204 to decrease as a distance from the back-side surface 102b of the substrate 102 towards the front-side surface 102f of the substrate increases.

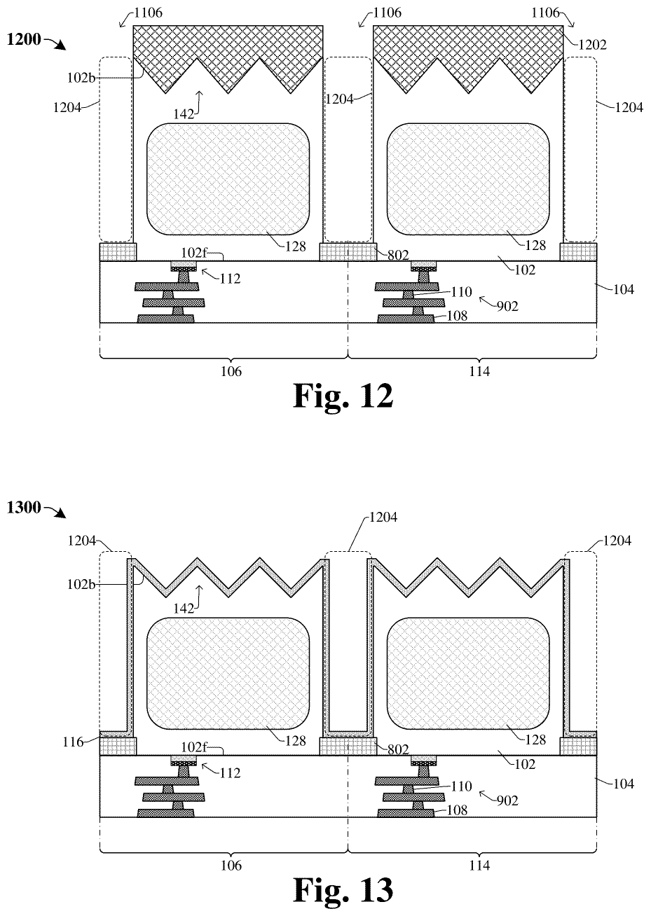

As shown in cross-sectional view 1300 of FIG. 13, the second patterned masking layer 1202 is removed. In some embodiments, the second patterned masking layer is removed by a chemical wash, an etching process, an ashing process, or other suitable removal process. A first dielectric layer 116 is deposited over exposed surfaces of the STI structures 802 and the substrate 102. In some embodiments, the first dielectric layer 116 is formed lining sidewalls and a bottom surface of the isolation trench 1204 which are respectively a top surface of the STI structures 802 and sidewalls of the substrate 102. Furthermore, the first dielectric layer 116 is formed over the back-side surface 102b of the substrate 102 such as the plurality of protrusions 142. In some embodiments, the first dielectric layer 116 may be or comprise a high-k dielectric layer including hafnium oxide (HfO₂), titanium oxide (TiO₂), hafnium zirconium oxide (HfZrO), tantalum oxide (Ta₂O₃), hafnium silicon oxide (HfSiO₄), zirconium oxide (ZrO₂), zirconium silicon oxide (ZrSiO₂), etc. In some embodiments, the first dielectric layer 116 may be deposited by a deposition technique (e.g., PVD, CVD, PE-CVD, ALD, etc.). In some embodiments, the first dielectric layer 116 is formed with a first thickness of 50 A to 1000 A or some other suitable value.

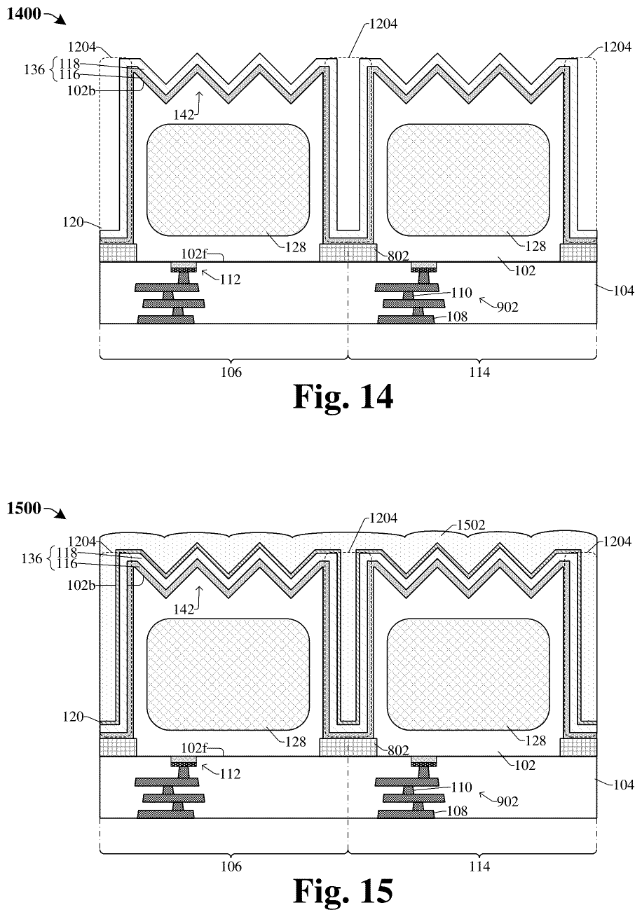

As shown in cross-sectional view 1400 of FIG. 14, a second dielectric layer 118 is deposited over exposed surfaces of the first dielectric layer 116. The second dielectric layer 118 is formed within the isolation trench 1204 on the first dielectric layer 116 and over the backside surface of the substrate on the first dielectric layer 116 and aligned over the plurality of protrusions 142. In some embodiments, the second dielectric layer 118 is formed through a deposition process like ALD or another suitable process (e.g., PVD, CVD, PE-CVD, etc.). In other embodiments, the second dielectric layer 118 is formed with a liquid oxide process. For example, the second dielectric layer 118 can be deposited with a liquid phase process using a liquid precursor (e.g., sol-gel). In other examples, the second dielectric layer 118 is deposited with a sin on process. The second dielectric layer 118 can be or comprise aluminum oxide (Al₂O₃), hafnium oxide (HfO₂), ZrO₂, titanium oxide (TiO₂), silicon oxide (SiO₂, tantalum Oxide (Ta₂O₅), or the like. In some embodiments, the second dielectric layer 118 is formed with a second thickness of 20 A to 100 A. The first and second dielectric layers 116, 118 form a high absorption structure 136.

As shown in cross-sectional view 1500 of FIG. 15, a liner layer 120 is deposited on the second dielectric layer 118. The liner layer 120 is deposited within the isolation trench 1204 on the second dielectric layer 118 and over the back-side surface 102b of the substrate 102. As such, the liner layer 120 is formed over the plurality of protrusions 142. In some embodiments, the liner layer 120 is a zero barrier layer and can prevent diffusion. In some embodiments, the liner layer 120 can be or comprise an alloy of or material stack including tantalum, tantalum nitride copper, aluminum, tungsten, rhodium, ruthenium, silver, gold, cobalt, iron, molybdenum, titanium, chromium or some other conductive material or metal. In other embodiments, the liner layer 120 can be or comprise a low-k dielectric. The liner layer 120 can be deposited by a deposition process (e.g., PVD, CVD, PE-CVD, ALD, etc.). In some embodiments, the liner layer 120 is formed with a third thickness of 0 A to 500 A. In some embodiments (not shown), the liner layer 120 is omitted.

A conductive layer 1502 is formed within the isolation trench 1204 and over the back-side surface 102b of the substrate 102 overlying the plurality of protrusions 142. The conductive layer 1502 is formed between inner sidewalls of the liner layer 120 within the isolation trench 1204 thereby filling a center portion of the isolation trench 1204. In some embodiments, the conductive layer 1502 is deposited having an upper surface comprising a plurality of curved surfaces arranged over the plurality of protrusions 142 that intersect one another. The conductive layer 1502 can be or comprise metal, copper, aluminum, tungsten, rhodium, ruthenium, silver, gold, cobalt, iron, molybdenum, titanium, chromium or another suitable conductive material and be deposited by a deposition process (e.g., PVD, CVD, PE-CVD, ALD, etc.).

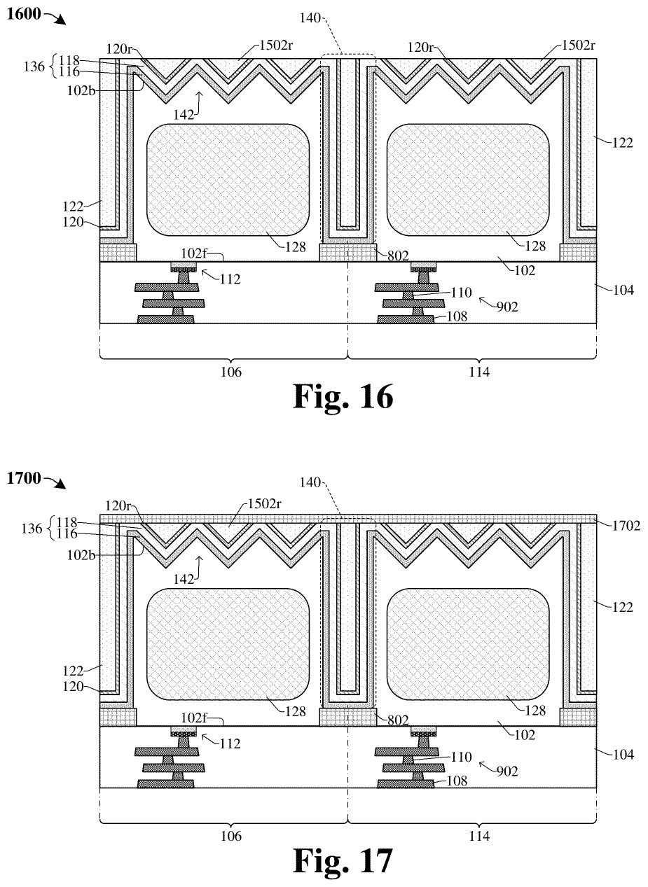

As shown in cross-sectional view 1600 of FIG. 16, a removal process (also referred to as a first removal process) is performed to remove the liner layer 120 and the conductive layer 1502 from over the photodetector 128 aligned over the plurality of protrusions 142. In some embodiments the removal process is a planarization process (e.g., a chemical mechanical planarization process) thereby forming a substantially flat surface aligned with an upper surface. The removal process forms a reflective element 122 from the conductive layer 1502 within the isolation trench 1204 (e.g., of FIG. 15) wherein the liner layer 120 remains within the isolation trench 1204 (e.g., of FIG. 15) and has a common top surface with the reflective element 122. The removal process forms a trench isolation structure 140 within the isolation trench 1204 (e.g., of FIG. 15) where the isolation structure 140 has a high absorption structure 136 that comprises the first and second dielectric layers 116, 118. The trench isolation structure 140 further includes the liner layer 120 and the reflective element 122.

In some embodiments, the removal process removes a portion of the second dielectric layer 118, the liner layer 120, and the conductive layer 1502 (e.g., of FIG. 15) over the plurality of protrusions 142. A liner remnant 120r of the liner layer 120 remains on the second dielectric layer 118 over the plurality of protrusions 142 and a conductive layer remnant 1502r of the conductive layer 1502 remains on the liner remnant 120r over the plurality of protrusions 142. As such, after the removal process, portions of the liner layer 120 and the conductive layer 1502 remain over the plurality of protrusions 142.

As shown in cross-sectional view 1700 of FIG. 17, a third dielectric layer 1702 is formed over the trench isolation structure 140, the liner remnant 120r, the conductive layer remnant 1502r, and the second dielectric layer 118 in a region over the plurality of protrusions 142. The third dielectric layer 1702 can be deposited by a deposition process (e.g., PVD, CVD, PE-CVD, ALD, etc.). The third dielectric layer 1702 can be or comprise aluminum oxide (Al₂O₃), hafnium oxide (HfO₂), ZrO₂, titanium oxide (TiO₂), silicon oxide (SiO₂, tantalum Oxide (Ta₂O₅), or the like. In some embodiments, the third dielectric layer 1702 is the same material as the second dielectric layer 118. In other embodiments, the third dielectric layer 1702 is a different material relative to the second dielectric layer 118. Material selection for the third dielectric layer is dependent on a wavelength of light associated with the pixel regions 106, 114.

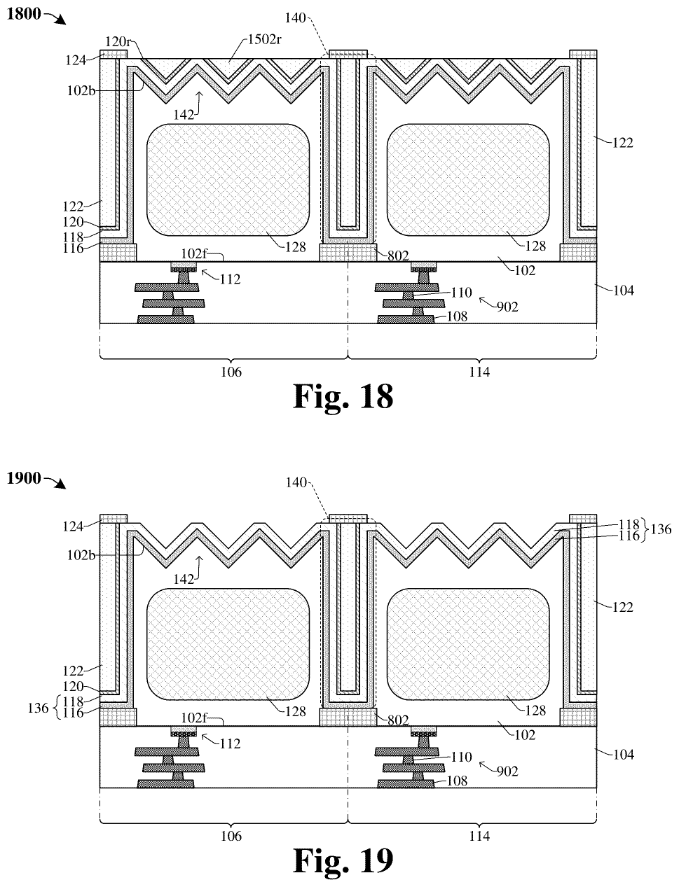

As shown in cross-sectional view 1800 of FIG. 18, the third dielectric layer 1702 (e.g., of FIG. 17) is patterned to form a dielectric cap 124 over the trench isolation structure and the liner layer 120 and to expose the liner remnant 120r and the conductive layer remnant 1502r over the plurality of protrusions 142. The third dielectric layer 1702 is patterned according to an appropriate patterning process, for example, patterning processes described earlier herein.

As shown in cross-sectional view 1900 of FIG. 19, the liner remnant 120r and the conductive layer remnant 1502r (e.g., of FIG. 18) over the plurality of protrusions 142 are removed by a removal process (also referred to as a second removal process), for example, a chemical wash, an etching process, an ashing process, or the like. After the removal process, the top surface of the second dielectric layer 118 is exposed in the region over the plurality of protrusions 142. In some examples, the first removal process associated with FIG. 16 is different than the second removal process associated with FIG. 19.

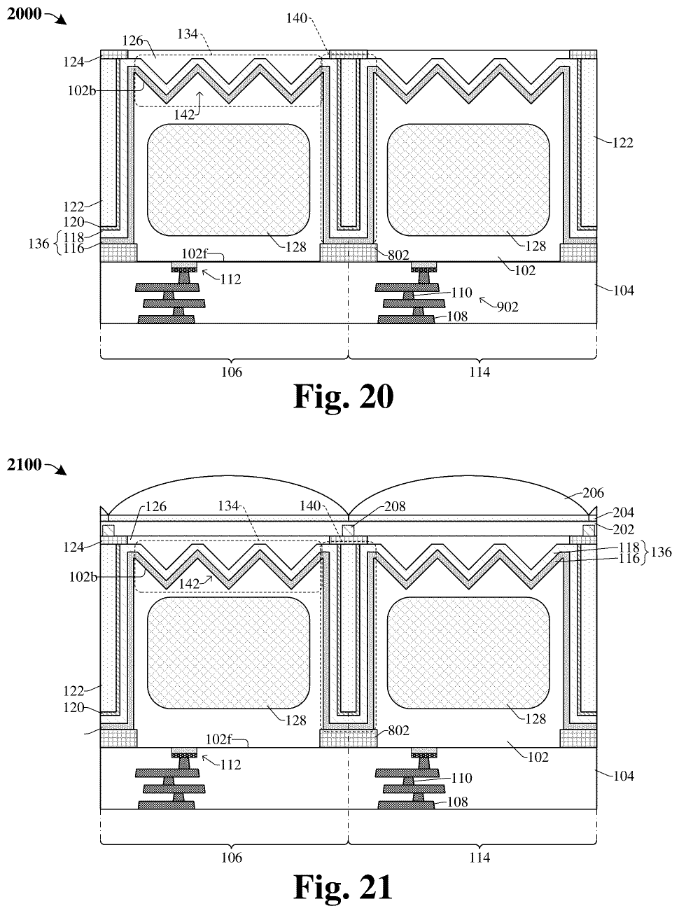

As shown in cross-sectional view 2000 of FIG. 20, an absorption layer 126 is formed on the second dielectric layer 118 over the plurality of protrusions 142 and between inner sidewalls of the dielectric cap 124. The absorption layer 126 can be or comprise an oxide (e.g., silicon oxide). The absorption layer 126 can be deposited by a deposition process (e.g., PVD, CVD, PE-CVD, ALD, etc.). In some embodiments, absorption layer 126 may be deposited to have an upper surface comprising a plurality of curved surfaces arranged over the plurality of protrusions 142. In some embodiments, the plurality of curved surfaces may be removed by a subsequent planarization process (e.g., a chemical mechanical planarization process) to form a substantially planar upper surface. The high absorption structure 136 in combination with the absorption layer 126 aligned over the plurality of protrusions 142 form a radiation absorption region 134.

As shown in cross-sectional view 2100 of FIG. 21, a grid structure 208 is formed on the dielectric cap 124. A lower dielectric layer 202 is formed over the grid structure 208 and on the absorption layer 126 and the dielectric cap 124. A plurality of light filters 204 are formed on the lower dielectric layer 202 and a plurality of micro-lenses 206 are formed on the plurality of light filters 204. In some embodiments, the plurality of light filters 204 may be formed by forming a color filter layer and patterning the color filter layer. The color filter layer is formed of a material that allows for the transmission of radiation (e.g., light) having a specific range of wavelength, while blocking light of wavelengths outside of the specified range. In some embodiments, the plurality of micro-lenses 206 may be formed by depositing a micro-lens material above the plurality of light filters 204 (e.g., by a spin-on method or a deposition process). A micro-lens template (not shown) having a curved upper surface is patterned above the micro-lens material. In some embodiments, the micro-lens template may comprise a photoresist material exposed using a distributing exposing light dose (e.g., for a negative photoresist more light is exposed at a bottom of the curvature and less light is exposed at a top of the curvature), developed and baked to form a rounding shape. The plurality of micro-lenses 206 are then formed by selectively etching the micro-lens material according to the micro-lens template.

In this manner, an improved image sensor chip is provided featuring a BSI structure having a trench isolation structure with a reflective element, and a high absorption structure that extends from the trench isolation structure to over a radiation absorption region aligned above a plurality of protrusions over a photodetector. By combining the plurality of protrusions with the high absorption structure in the radiation absorption region, and the reflective element within the trench isolation structure, the image sensor can achieve improved MTF performance and improved QE.

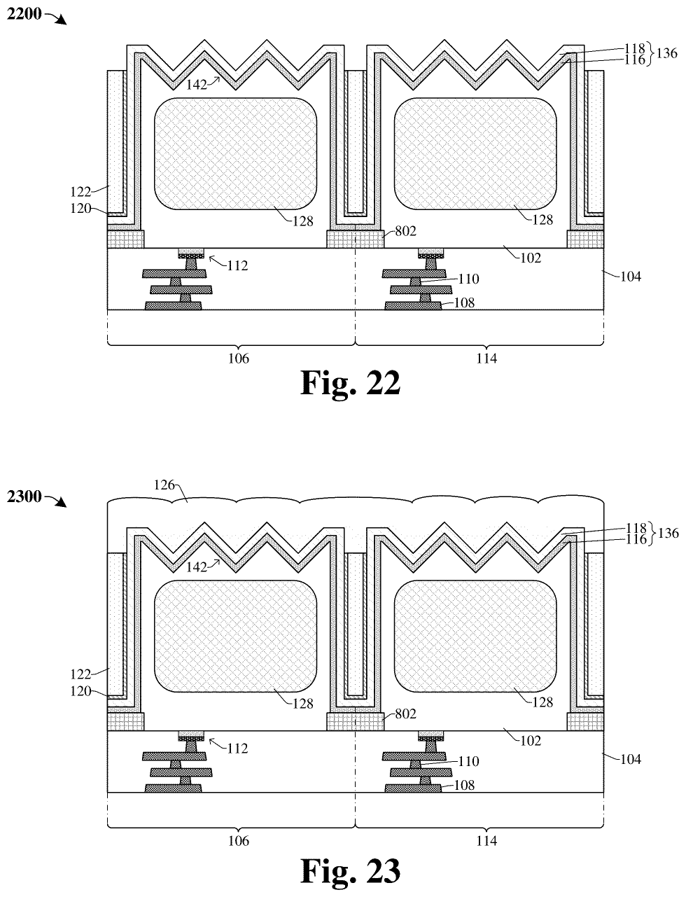

FIGS. 22-25 illustrate various views 2200-2500 of some embodiments of a method for forming a semiconductor device or an image sensor including a high absorption structure and a trench isolation structure with a reflective element. Although the various views 2200-2500 shown in FIGS. 22-25 are described with reference to the method, it will be appreciated that the structures shown in FIGS. 22-25 are not limited to the method but rather may stand alone separate of the method. Further, although FIGS. 22-25 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part. Furthermore, although the method describes the formation of a BSI sensor, it will be appreciated that the disclosed trench isolation structure may also be used with front-side image (FSI) sensor.

The method of FIG. 22 discussed below is subsequent to FIG. 15. As such, the features discussed in accordance with FIG. 22 originate with the structure of FIG. 15.

As shown in cross-sectional view 2200 of FIG. 22, the conductive layer 1502 (e.g., of FIG. 15) and the liner layer 120 undergo a removal process (also referred to as a first removal process), to remove the liner layer 120 and the conductive layer 1502 from the top surface of the second dielectric layer 118 aligned over the photodetector. The removal process can be, for example, a chemical wash, an etching process, an ashing process, or the like. After the removal process, a reflective element 122 is formed within the isolation trench 1204 (e.g., of FIG. 15) from the conductive layer 1502 and a top surface of the second dielectric layer 118 over the photodetector is exposed. The liner layer 120 and the conductive layer 1502 aligned over the plurality of protrusions 142 are removed and a top surface of the liner layer 120 and the reflective element 122 within the isolation trench is recessed below the top surface of the second dielectric layer 118. In some embodiments, the first removal process removes (not shown) a top portion of the second dielectric layer 118.

As shown in cross-sectional view 2300 of FIG. 23, an absorption layer 126 is formed on the second dielectric layer 118 and formed between inner sidewalls of the second dielectric layer 118 aligned over top surfaces of the reflective element 122 and the liner layer 120. In some embodiments, the absorption layer 126 is deposited having an upper surface comprising a plurality of curved surfaces arranged over the plurality of protrusions 142 that intersect one another. As such, the upper surface of the absorption layer 126 is irregular and non-planar. The absorption layer 126 can be deposited by a deposition process (e.g., PVD, CVD, PE-CVD, ALD, etc.).

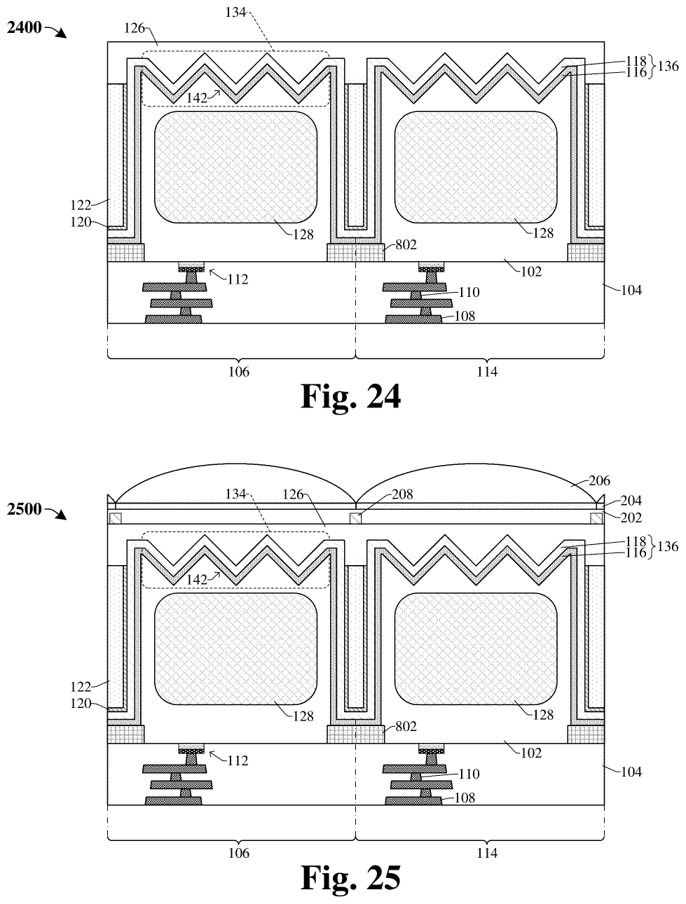

As shown in cross-sectional view 2400 of FIG. 24, a removal process (also referred to as a second removal process) is performed on the absorption layer 126. As such, the upper surface of the absorption layer 126 comprising the plurality of curved surfaces is removed and a top surface of the absorption layer 126 is substantially planar. In some embodiments, the removal process is a planarization process (e.g., a chemical mechanical planarization process). In some embodiments, the first removal process of FIG. 23 and the second removal process of FIG. 24 are different types of removal processes.

As shown in cross-sectional view 2500 of FIG. 25, a grid structure 208 is formed on the absorption layer 126. A lower dielectric layer 202 is formed over the grid structure 208 and on the absorption layer 126. A plurality of light filters 204 are formed on the lower dielectric layer 202 and a plurality of micro-lenses 206 are formed on the plurality of light filters 204. The grid structure 208, lower dielectric layer 202, the plurality of light filters 204, and the plurality of micro-lenses 206 are formed according to aspects previously described in accordance with FIG. 21.

Accordingly, an improved image sensor chip is provided featuring a BSI structure having a trench isolation structure with a reflective element, and a high absorption structure that extends from the trench isolation structure to over a radiation absorption region aligned above a plurality of protrusions over a photodetector. By combining the plurality of protrusions with the high absorption structure in the radiation absorption region, and the reflective element within the trench isolation structure, the image sensor can achieve improved MTF performance and improved QE.

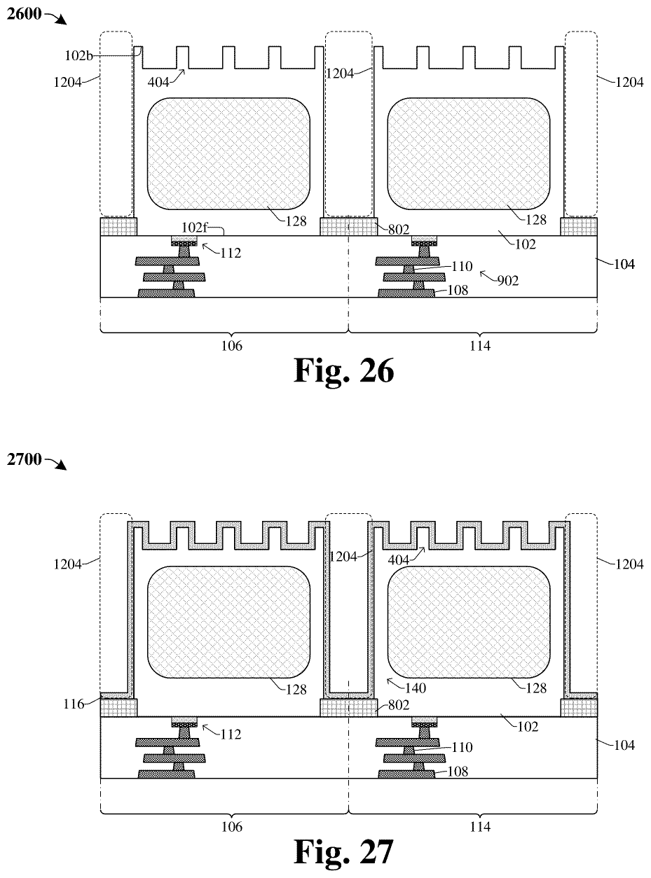

FIGS. 26-31 illustrate various views 2600-3100 of some embodiments of a method for forming a semiconductor device or an image sensor including a high absorption structure and a trench isolation structure with a reflective element. Although the various views 2600-3100 shown in FIGS. 26-31 are described with reference to the method, it will be appreciated that the structures shown in FIGS. 26-31 are not limited to the method but rather may stand alone separate of the method. Further, although FIGS. 26-31 are described as a series of acts, it will be appreciated that these acts are not limited in that the order of the acts can be altered in other embodiments, and the methods disclosed are also applicable to other structures. In other embodiments, some acts that are illustrated and/or described may be omitted in whole or in part. Furthermore, although the method describes the formation of a BSI sensor, it will be appreciated that the disclosed trench isolation structure may also be used with a FSI sensor.

The method steps discussed in accordance with the cross-sectional view 2600 of FIG. 26 is subsequent to FIG. 12 with some alternative features. Specifically, FIG. 26 shows a plurality of protrusions 404 that are rectangular rather than the plurality of protrusions 142 of FIG. 12 that are triangular. Furthermore, FIG. 26 shows the image sensor after the second patterned masking layer 1202 of FIG. 12 is removed. FIG. 26 further shows the isolation trench 1204 aligned over the STI structures 802.

As shown in cross-sectional view 2700 of FIG. 27, a first dielectric layer 116 is deposited over exposed surfaces of the STI structures 802 and the substrate 102. In some embodiments, the first dielectric layer 116 is formed lining sidewalls and a bottom surface of the isolation trench 1204 which are respectively a top surface of the STI structures 802 and sidewalls of the substrate 102. Furthermore, the first dielectric layer 116 is formed over the back-side surface 102b on the plurality of protrusions 142. Since the plurality of protrusions 142 are rectangular in shape, the first dielectric layer 116 creates a meandered structure on the plurality of protrusions 142. In some embodiments, the first dielectric layer 116 may be or comprise a high-k dielectric layer including hafnium oxide (HfO₂), titanium oxide (TiO₂), hafnium zirconium oxide (HfZrO), tantalum oxide (Ta₂O₃), hafnium silicon oxide (HfSiO₄), zirconium oxide (ZrO₂), zirconium silicon oxide (ZrSiO₂), etc. In some embodiments, the first dielectric layer 116 may be deposited by a deposition technique (e.g., PVD, CVD, PE-CVD, ALD, etc.).

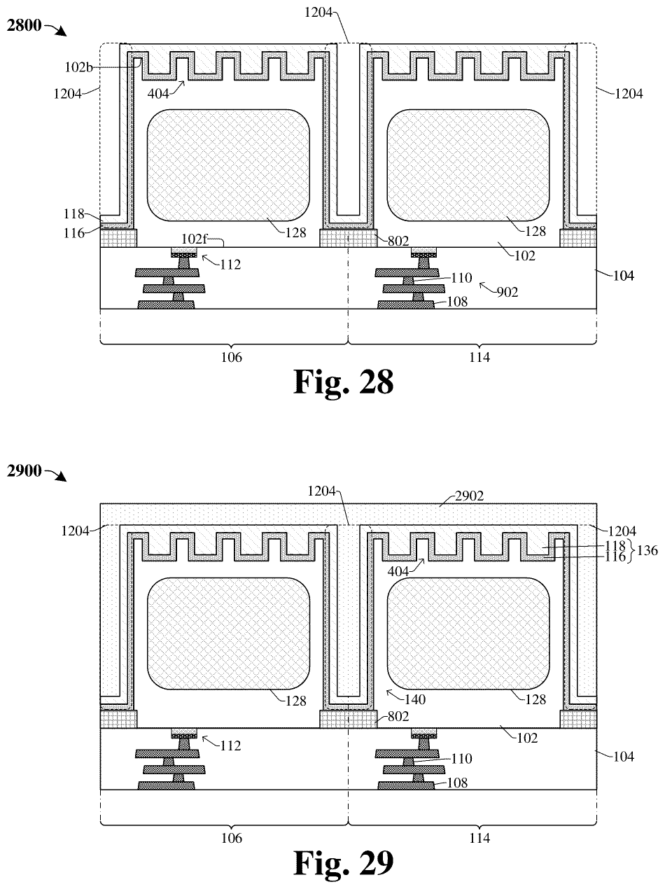

As shown in cross-sectional view 2800 of FIG. 28, a second dielectric layer 118 is deposited over exposed surfaces of the first dielectric layer 116. The second dielectric layer 118 is formed within the isolation trench 1204 on the first dielectric layer 116 and formed over the plurality of protrusions 404 on the first dielectric layer 116. Furthermore, the second dielectric layer 118 fills open regions between the plurality of protrusion forming a substantially coplanar top surface of the second dielectric layer 118. In some embodiments, the second dielectric layer 118 is formed through a deposition process like ALD or another suitable process (e.g., PVD, CVD, PE-CVD, etc.). The second dielectric layer 118 can be or comprise aluminum oxide (Al₂O₃), hafnium oxide (HfO₂), ZrO₂, titanium oxide (TiO₂), silicon oxide (SiO₂, tantalum Oxide (Ta₂O₅), or the like.

As shown in cross-sectional view 2900 of FIG. 29, a conductive layer 2902 is formed within the isolation trench 1204 and over the back-side surface 102b of the substrate 102 overlying the plurality of protrusions 404. The conductive layer 2902 is formed between inner sidewalls of the liner layer 120 within the isolation trench 1204 thereby filling a center portion of the isolation trench 1204. As such, the conductive layer 2902 extends from the isolation trench 1204 to above a top surface of the second dielectric layer 118. In other embodiments (not shown) a liner layer is formed along the second dielectric layer 118 in the isolation trench 1204 and in the region above the plurality of protrusions 404.

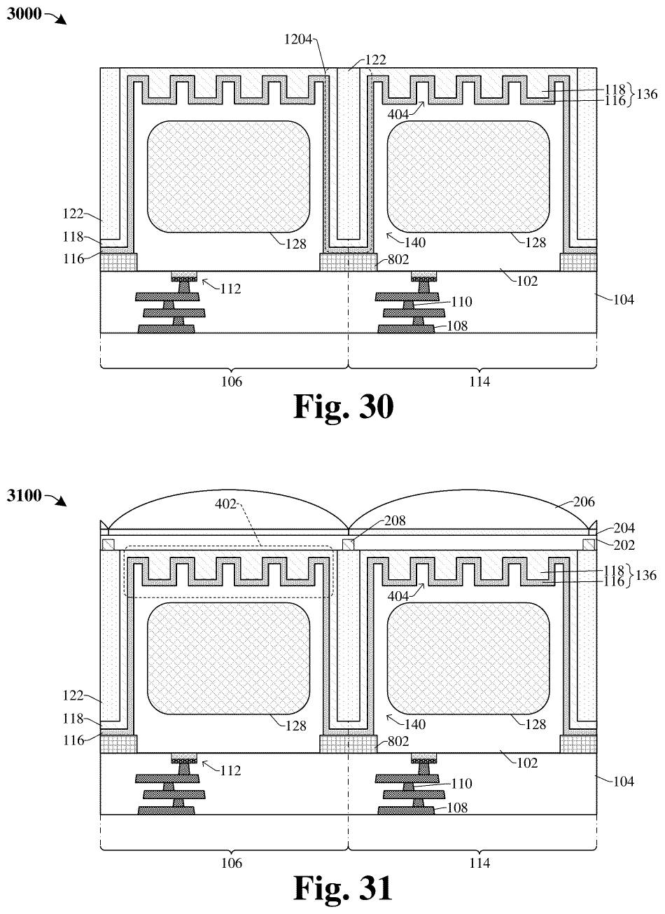

As shown in cross-sectional view 3000 of FIG. 30, a removal process is performed on the conductive layer 2902 (e.g., of FIG. 29) thereby removing the conductive layer 2902 over the plurality of protrusions 404. After the removal process, a reflective element 122 is formed within the isolation trench 1204 and having a top surface level with a top surface of the second dielectric layer 118. In some embodiments, the removal process can be a planarization process (e.g., a chemical mechanical planarization process).

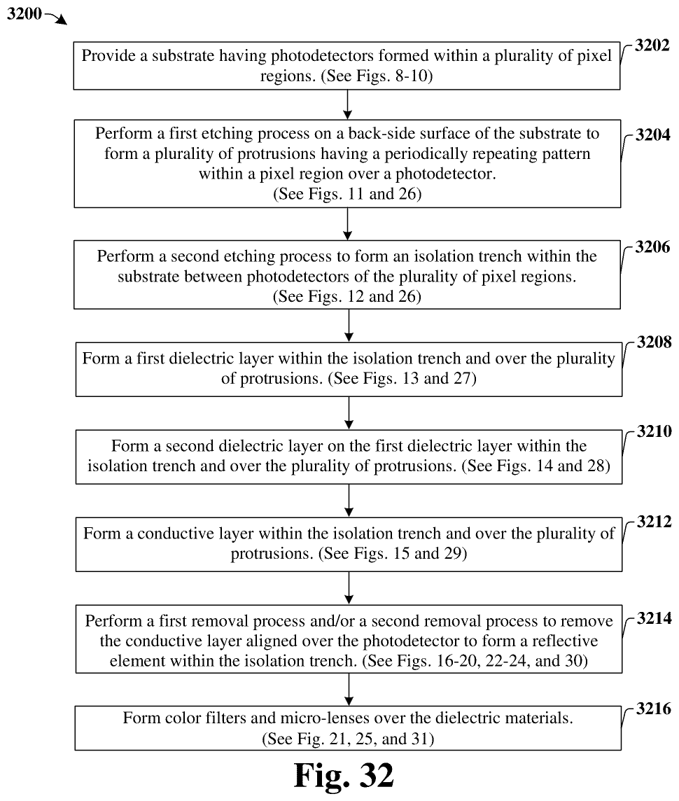

As shown in cross-sectional view 3100 of FIG. 31, a grid structure 208 is formed on the reflective element 122. A lower dielectric layer 202 is formed over the grid structure 208 and on the second dielectric layer 118 and reflective element 122. A plurality of light filters 204 are formed on the lower dielectric layer 202 and a plurality of micro-lenses 206 are formed on the plurality of light filters 204. The grid structure 208, lower dielectric layer 202, the plurality of light filters 204, and the plurality of micro-lenses 206 are formed according to aspects previously described in accordance with FIG. 21.

As such, the above presents a first method associated with FIGS. 8-21, a second method associated with FIGS. 22-25, and a third method associated with FIGS. 26-31. The first method has more processing steps relative to the second and third method and provides fabrication processes that can achieve larger feature sizes and/or more precise feature formation, for example, for the trench isolation structure and in the radiation absorption region. The second method has less processing steps relative to the first method but more processing steps relative to the third method. The second method can realize moderate feature sizes, for example, for the trench isolation structure and the radiation absorption region, with less precision relative to the first method. The third method has less processing steps relative to the first and second methods and therefore is cost effective and is suited for image sensors with smaller features or less precision for formation of the trench isolation structure and the radiation absorption region.

FIG. 32 illustrates a flow diagram of some embodiments of a method 3200 of forming an image sensor including a high absorption structure and a trench isolation structure with a reflective element.

While method 3200 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 3202, a substrate is provided having photodetectors formed within a plurality of pixel regions. FIGS. 8-10 illustrate cross-sectional views 800 through 1000 of some embodiments corresponding to act 3202.

At 3204, a first etching process is performed on a back-side surface of the substrate to form a plurality of protrusions having a periodically repeating pattern within a pixel region of the plurality of pixel regions over a photodetector of the pixel region. In some examples, the periodically repeating pattern is triangular in shape, in other examples the periodically repeating pattern is rectangular in shape. FIGS. 11 and 26 illustrate cross-sectional views 1100 and 2600 of some embodiments corresponding to act 3204.

At 3206, a second etching process is performed to form an isolation trench within the substrate and between photodetectors of the plurality of pixel regions. FIGS. 12 and 26 illustrate cross-sectional views 1200 and 2600 of some embodiments corresponding to act 3206.

At 3208, a first dielectric layer is formed within the isolation trench and over the plurality of protrusions of the substrate. FIGS. 13 and 27 illustrate cross-sectional views 1300 and 2700 of some embodiments corresponding to act 3208.

At 3210, a second dielectric layer is formed on the first dielectric layer within the isolation trench and over the plurality of protrusions. The first and second dielectric layers form a high absorption structure over the photodetector. FIGS. 14 and 28 illustrate cross-sectional views 1400 and 2800 of some embodiments corresponding to act 3210.

At 3212, a conductive layer is formed within the isolation trench and over the plurality of protrusions. In some examples, the conductive layer is formed over the second dielectric layer. FIGS. 15 and 29 illustrate cross-sectional views 1500 and 2900 of some embodiments corresponding to act 3212.

At 3214, one or more of a first removal process or a second removal process are performed to remove the conductive layer aligned over the photodetectors to form a reflective element within the isolation trench. FIGS. 16-20, 22-24, and 30 illustrate cross-sectional views 1600-2000, 2200-2400, and 3000 of some embodiments corresponding to act 3214.

At 3214, one or more of a first removal process or a second removal process are performed to remove the conductive layer aligned over the photodetectors to form a reflective element within the isolation trench. FIGS. 16-20, 22-24, and 30 illustrate cross-sectional views 1600-2000, 2200-2400, and 3000 of some embodiments corresponding to act 3214.

At 3216, color filters are formed over the dielectric materials. FIGS. 21, 25, and 31 illustrate cross-sectional views 2100, 2500, and 3100 of some embodiments corresponding to act 3216.

Accordingly, the present disclosure relates to an image sensor having an enhanced BSI structure with a reflective element and having a high absorption structure over a photodetector that improves QE and MTF.

In some embodiments, the present disclosure relates to a semiconductor device with a photodetector disposed in a substrate where the substrate has a plurality of protrusions over the photodetector. An isolation structure is disposed in the substrate and laterally surrounding the photodetector, where the isolation structure has a reflective element with a conductive material. A first dielectric layer is over the photodetector, where the first dielectric layer extends vertically into the substrate and is disposed between the reflective element and the substrate. A top surface of the first dielectric layer is over the plurality of protrusions is irregular. A second dielectric layer is on the first dielectric layer and over the photodetector. A top surface of the second dielectric layer over the plurality of protrusions is irregular. The second dielectric layer extends vertically into the substrate along a surface of the first dielectric layer. The second dielectric layer is disposed along sidewalls and a bottom surface of the reflective element.

In some embodiments, the present disclosure relates to an image sensor with a substrate that has a front-side surface opposite a back-side surface. The substrate has a first plurality of protrusions on the back-side surface. A first photodetector is disposed within the substrate and underlying the first plurality of protrusions. A reflective element is disposed within the substrate and laterally offset from the first photodetector. The reflective element extends from the back-side surface towards the front-side surface. A high absorption structure is disposed over the back-side surface of the substrate and extends into the substrate, where the high absorption structure separates a bottom surface and sidewalls of the reflective element from the substrate. The high absorption structure has a first dielectric layer contacting the first plurality of protrusions and a second dielectric layer on the first dielectric layer. The first and second dielectric layers extend over the back-side surface of the substrate. A liner layer is between the second dielectric layer and the reflective element, where the liner layer is laterally offset from the back-side surface of the substrate.

In some embodiments, the present disclosure relates to a method of forming an image sensor. The method includes forming a photodetector within a substrate. The method includes patterning the substrate to form an isolation trench in the substrate and laterally surrounding the photodetector. The method includes forming a first dielectric layer within the isolation trench, where the first dielectric layer is formed lining a bottom surface and sidewalls of the isolation trench, and the first dielectric layer is formed over a back-side surface of the substrate. The method includes forming a second dielectric layer within the isolation trench on the first dielectric layer and over the back-side surface of the substrate. The method includes forming a liner layer within the isolation trench on the second dielectric layer and over the back-side surface of the substrate. The method includes forming a conductive layer within the isolation trench on the liner layer and over the back-side surface of the substrate. The method includes performing a first removal process to remove the liner layer and the conductive layer from a surface of the second dielectric layer aligned over the photodetector thereby forming a reflective element within the isolation trench.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a photodetector disposed in a substrate, wherein the substrate has a plurality of protrusions over the photodetector;
an isolation structure disposed in the substrate and laterally surrounding the photodetector, wherein the isolation structure comprises a reflective element that comprises a conductive material;
a first dielectric layer over the photodetector, wherein the first dielectric layer extends substantially vertically into the substrate and is disposed between the reflective element and the substrate, and a top surface of the first dielectric layer over the plurality of protrusions is irregular; and
a second dielectric layer on the first dielectric layer and over the photodetector, wherein a top surface of the second dielectric layer over the plurality of protrusions is irregular, wherein the second dielectric layer extends substantially vertically into the substrate along a surface of the first dielectric layer, and wherein the second dielectric layer is disposed along sidewalls and a bottom surface of the reflective element.

2. The semiconductor device of claim 1, further comprising:
a liner layer disposed between the reflective element and the second dielectric layer, wherein the liner layer is disposed along the bottom surface of the reflective element.

3. The semiconductor device of claim 2, wherein the liner layer extends from a horizontal surface that is common with a top surface of the reflective element and the second dielectric layer.

4. The semiconductor device of claim 1, wherein the plurality of protrusions are on a back-side surface of the substrate over the photodetector and arranged between a top portion of the photodetector and a top surface of the reflective element.

5. The semiconductor device of claim 4, wherein the plurality of protrusions comprise a periodically repeating pattern of triangular shaped protrusions.

6. The semiconductor device of claim 4, wherein the plurality of protrusions comprises a periodically repeating pattern of rectangular shaped protrusions.

7. The semiconductor device of claim 1, wherein an upper surface of the second dielectric layer periodically extends from above a top surface of the first dielectric layer to a plane below the top surface of the first dielectric layer.

8. An image sensor, comprising:
a substrate comprising a front-side surface opposite a back-side surface, wherein the substrate comprises a first plurality of protrusions on the back-side surface;
a first photodetector disposed within the substrate and underlying the first plurality of protrusions;
a reflective element disposed within the substrate and laterally offset from the first photodetector, wherein the reflective element extends from the back-side surface towards the front-side surface;
a high absorption structure disposed over the back-side surface of the substrate and extending into the substrate, wherein the high absorption structure separates a bottom surface and sidewalls of the reflective element from the substrate, wherein the high absorption structure comprises a first dielectric layer contacting the first plurality of protrusions and a second dielectric layer on the first dielectric layer, wherein the first and second dielectric layers extend over the back-side surface of the substrate; and
a liner layer between the second dielectric layer and the reflective element, wherein the liner layer is laterally offset from the back-side surface of the substrate.

9. The image sensor of claim 8, further comprising:
an absorption layer disposed over the high absorption structure.

10. The image sensor of claim 9, further comprising:
a dielectric cap disposed on the reflective element, wherein the absorption layer is disposed between inner sidewalls of the dielectric cap, and wherein the dielectric cap and the absorption layer have top horizontal surfaces that are substantially coplanar with one another.

11. The image sensor of claim 10, wherein the dielectric cap extends from a top surface of the second dielectric layer to inner sidewalls of the second dielectric layer, and wherein the dielectric cap directly contacts a top surface of the liner layer and a top surface of the reflective element.

12. The image sensor of claim 9, wherein the absorption layer is disposed between inner sidewalls of the second dielectric layer and extends from a horizontal surface common with top surfaces of the liner layer and the reflective element to a top surface of the second dielectric layer.

13. The image sensor of claim 9, wherein the absorption layer extends below a top surface of the first and second dielectric layers and a top surface of the reflective element in a region aligned over the first photodetector.

14. The image sensor of claim 8, further comprising:
a second photodetector disposed within the substrate, wherein the reflective element is spaced between the first photodetector and the second photodetector; and
wherein the substrate comprises a second plurality of protrusions on the back-side surface and overlying the second photodetector, wherein the first plurality of protrusions have a first shape and the second plurality of protrusions have a second shape different from the first shape.

15. A method of forming an image sensor, the method comprising:
forming a photodetector within a substrate;
patterning the substrate to form an isolation trench in the substrate and laterally surrounding the photodetector;
forming a first dielectric layer within the isolation trench, wherein the first dielectric layer is formed lining a bottom surface and sidewalls of the isolation trench, and the first dielectric layer is formed over a back-side surface of the substrate;
forming a second dielectric layer within the isolation trench on the first dielectric layer and over the back-side surface of the substrate;
forming a liner layer within the isolation trench on the second dielectric layer and over the back-side surface of the substrate;
forming a conductive layer within the isolation trench on the liner layer and over the back-side surface of the substrate; and
performing a first removal process to remove the liner layer and the conductive layer from a surface of the second dielectric layer aligned over the photodetector to form a reflective element within the isolation trench.

16. The method of claim 15, further comprising:
patterning the back-side surface of the substrate to form a plurality of protrusions on the back-side surface of the substrate, wherein the plurality of protrusions are formed over the photodetector;
forming the first dielectric layer on the plurality of protrusions;
forming the second dielectric layer on the first dielectric layer over the plurality of protrusions, wherein after the first removal process, the liner layer and the conductive layer remain over the plurality of protrusions; and
performing a second removal process to remove the liner layer and the conductive layer from over the plurality of protrusions, wherein the first removal process is a different from the second removal process.

17. The method of claim 16, wherein the second removal process includes:
forming a third dielectric layer over the reflective element, a remnant of the conductive layer over the plurality of protrusions, and the second dielectric layer;
patterning the third dielectric layer to form a dielectric cap over the reflective element and exposing the remnant of the conductive layer over the plurality of protrusions;
removing the remnant of the conductive layer from over the plurality of protrusions; and
after performing the second removal process, forming an absorption layer over the plurality of protrusions between inner sidewalls of the dielectric cap and a top surface of the second dielectric layer.

18. The method of claim 15, further comprising:
patterning the substrate to form a plurality of protrusions on the back-side surface of the substrate over the photodetector, wherein after the first removal process, a top surface of the second dielectric layer over the photodetector is exposed, and a top surface of the reflective element is recessed below the top surface of the second dielectric layer.

19. The method of claim 18, wherein after performing the first removal process, the method further comprises:
forming an absorption layer over the second dielectric layer, within the plurality of protrusions, and over the reflective element, wherein a top surface of the absorption layer is non-planar; and
performing a second removal process on the absorption layer, wherein after the second removal process, the top surface of the absorption layer is substantially planar.

20. The method of claim 15, wherein the first dielectric layer and the second dielectric layer comprise different dielectric materials relative to one another, the liner layer comprises a first conductive material, and the conductive layer comprises a second conductive material that is different from the first conductive material.
